(19) United States
(12) Patent Application Publication
(10) Pub. No.: US 2025/0015239 A1
(43) Pub. Date: Jan. 9, 2025

(54) MICROLENS SUBSTRATE, DISPLAY DEVICE AND METHOD FOR MANUFACTURING MICROLENS SUBSTRATE

(71) Applicant: BOE Technology Group Co., Ltd., Beijing (CN)

(72) Inventors: Dongfei HOU, Beijing (CN); Mengya SONG, Beijing (CN); Feng ZHANG, Beijing (CN); Zhao CUI, Beijing (CN); Liwen DONG, Beijing (CN); Zhijun LV, Beijing (CN); Detian MENG, Beijing (CN); Wenqu LIU, Beijing (CN); Yuqiao LI, Beijing (CN); Qi YAO, Beijing (CN)

(21) Appl. No.: 18/273,042

(22) PCT Filed: May 24, 2022
(86) PCT No.: PCT/CN2022/094786

§ 371 Date: Jul. 19, 2023

(51) Int. Cl. H01L 33/58

(52) U.S. Cl. CPC H01L 33/58; H01L 2933/0058

(57) ABSTRACT

A microlens substrate, a display device and a method for manufacturing a microlens substrate are provided. The microlens substrate includes: a base; a first lens pattern disposed on a side of the base and including a plurality of first microlenses distributed at intervals; a second lens pattern disposed on a side of the first lens pattern and including a plurality of second microlenses distributed at intervals, where an orthographic projection of at least one of the plurality of second microlens on the base is located between two orthographic projections of two adjacent first microlenses on the base.

### TECHNICAL FIELD

The present disclosure relates to the field of display technology, and in particular to a microlens substrate, a display device and a method for manufacturing a microlens substrate.

### BACKGROUND

With the development of industrial technology, the demand for miniaturization of optical devices is continuously increasing, so that microlenses emerge. The microlenses usually refer to lenses with an aperture ranging from micrometer scale to millimeter scale. When a certain number of microlenses are arranged on a base according to certain rules, a microlens substrate is formed. The microlens substrate can realize optical characteristics that conventional optical devices do not have, and use the optical characteristics to implement some special functions. For example, in the display field, glasses-free 3D can be implemented using the microlens substrate. However, using the existing microlens substrate is easy to cause the occurrence of light crosstalk phenomenon in a display device.

### SUMMARY

A purpose of the present disclosure is to provide a microlens substrate, a display device and a method for manufacturing a microlens substrate to reduce the occurrence of light crosstalk phenomenon.

According to an aspect of the present disclosure, a microlens substrate is provided, including:
a base;
a first lens pattern disposed on a side of the base and including a plurality of first microlenses distributed at intervals;
a second lens pattern disposed on a side of the first lens pattern and including a plurality of second microlenses distributed at intervals, where an orthographic projection of at least one of the plurality of second microlenses on the base is located between two orthographic projections of two adjacent first microlenses on the base.

Further, a distance between an orthographic projection of a second microlens on the base and an orthographic projection of a first microlens on the base is greater than or equal to zero and less than or equal to ¼ of a distance between two adjacent first microlenses.

Further, the microlens substrate further includes:
a first planarization layer covering light exiting surfaces of the plurality of first microlenses, where the light exiting surfaces of the plurality of first microlenses are respectively outward convex surfaces, and a refractive index of the first planarization layer is less than that of each of the plurality of first microlenses.

Further, the second lens pattern is disposed on a side of the first planarization layer away from the plurality of first microlenses, and light exiting surfaces of the plurality of second microlenses face away from the plurality of first microlenses.

Further, the microlens substrate further includes:
a second planarization layer covering the light exiting surfaces of the plurality of second microlenses, where the light exiting surfaces of the plurality of second microlenses are respectively outward convex surfaces, and a refractive index of the second planarization layer is less than that of each of the plurality of second microlenses.

Further, the refractive index of each of the plurality of first microlenses is 1.5 to 1.8: and/or
the refractive index of each of the plurality of second microlenses is 1.5 to 1.8: and/or
the refractive index of the first planarization layer is 1.3 to 1.6; and/or
the refractive index of the second planarization layer is 1.3 to 1.6.

Further, the microlens substrate further includes:
a light-transmitting inorganic layer disposed on the side of the first planarization layer away from the plurality of first microlenses, wherein the plurality of second microlenses are disposed on a surface of the light-transmitting inorganic layer away from the first planarization layer.

Further, a thickness of the first planarization layer is 5 μm to 30 μm: and/or
a thickness of each of the plurality of first microlenses is 5 μm to 30 μm: and/or
a thickness of the second planarization layer is 5 μm to 30 μm: and/or
a thickness of each of the plurality of second microlenses is 5 μm to 30 μm: and/or
a thickness of the light-transmitting inorganic layer is 250 nm to 350 nm.

Further, for each of the plurality of first microlenses and each of the plurality of second microlenses, at least one of an orthographic projection of the first microlens on the base or an orthographic projection of the second microlens on the base is circular or strip-shaped.

Further, when the orthographic projection of the first microlens on the base and the orthographic projection of the second microlens on the base are circular, a diameter of the orthographic projection of the first microlens on the base and a diameter of the orthographic projection of the second microlens on the base are 10 μm to 300 μm:
when the orthographic projection of the first microlenses on the base and the orthographic projection of the second microlens on the base are strip-shaped, a width of the orthographic projection of the first microlens on the base and a width of the orthographic projection of the second microlens on the base are 10 μm to 300 μm.

Further, materials for the plurality of first microlenses and/or the plurality of second microlenses include photoresist.

Further, for each of the plurality of first microlenses and each of the plurality of second microlenses, a shape of an orthographic projection of the first microlens on the base is the same as that of the second microlens on the base, an area of the orthographic projection of the first microlens on the base is the same as that of the second microlens on the base, and a distance between two adjacent first microlenses in a direction parallel to the base is the same as that between two adjacent second microlenses in the direction parallel to the base.

According to an aspect of the present disclosure, a display device is provided, including:
a display module;
the microlens substrate described above and disposed on a light exiting side of the display module.

According to an aspect of the present disclosure, a method of manufacturing a microlens substrate is provided, including:
providing a base;
forming a first lens pattern on a side of the base, where the first lens pattern includes a plurality of first microlenses distributed at intervals;
forming a second lens pattern on a side of the first lens pattern, where the second lens pattern includes a plurality of second microlenses distributed at intervals, and an orthographic projection of at least one of the plurality of second microlenses on the base is located between two orthographic projections of two adjacent first microlenses on the base.

Further, forming the first lens pattern includes: forming the first lens pattern through a first photoetching process;
forming the second lens pattern includes: forming the second lens pattern through a second photoetching process;
where a mask plate used in the first photoetching process and a mask plate used in the second photoetching process are the same mask plate.

In the microlens substrate, display device and method for manufacturing a microlens substrate according to the present disclosure, the first lens pattern includes a plurality of first microlenses distributed at intervals, the second lens pattern includes a plurality of second microlenses distributed at intervals, and the orthographic projection of at least one second microlens on the base is located between two orthographic projections of two adjacent first microlenses on the base. Therefore, in a direction parallel to the base, a gap between adjacent first microlens and second microlens is less than that between two adjacent first microlenses, which is equivalent to reducing the gap between two adjacent microlenses in the direction parallel to the base so that the occurrence of light crosstalk phenomenon can be reduced. At the same time, since the gap between two adjacent first microlenses is larger than that between adjacent first microlens and second microlens, that is, the gap between two adjacent first microlenses is larger, the problem of process failure due to the contact between adjacent lens units in the thermal reflow process in the related art can be solved.

### BRIEF DESCRIPTION OF THE DRAWINGS

FIG. 1 is a schematic diagram illustrating a display device in the related art.

FIG. 2 is a schematic diagram illustrating a microlens substrate in the related art.

FIG. 3 is a schematic diagram illustrating a microlens substrate according to an embodiment of the present disclosure.

FIG. 4 is a schematic diagram illustrating first microlenses and a base according to an embodiment of the present disclosure.

FIG. 5 is a schematic diagram illustrating the distribution of first microlenses and second microlenses in a direction parallel to a base according to an embodiment of the present disclosure.

FIG. 6 is another schematic diagram illustrating the distribution of first microlenses and second microlenses in a direction parallel to a base according to an embodiment of the present disclosure.

FIG. 7 is a schematic diagram illustrating a display device according to an embodiment of the present disclosure.

Description of reference signs: 1. base: 2. microlens: 3. light emitting unit: 4. red resistance block: 5. blue resistance block: 6. green resistance block: 7. first lens pattern: 701. first microlens: 8. first planarization layer: 9. second lens pattern: 901. second microlens: 10. second planarization layer: 11. light-transmitting inorganic layer: 12. display module: 13. black matrix.

### DETAILED DESCRIPTION OF THE EMBODIMENTS

Exemplary embodiments will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses consistent with some aspects of the present disclosure as detailed in the appended claims.

The terms used in the present disclosure are for the purpose of describing particular embodiments only, and are not intended to limit the present disclosure. Unless otherwise defined, technical or scientific terms used in this disclosure should have ordinary meaning as understood by one of ordinary skill in the art to which the disclosure belongs. “First”, “second” and similar words used in the specification and claims of the present disclosure do not represent any order, quantity or importance, but are used only to distinguish different components. Likewise, similar words such as “one”, “a” or “an” do not represent a quantity limit, but represent that there is at least one. “Plurality”, “multiple” or “several” means two or more. Unless otherwise indicated, similar words such as “front”, “rear”, “lower” and/or “upper” are only for convenience of description, and are not limited to one position or one spatial orientation. Similar words such as “including” or “including” mean that an element or an item appearing before “including” or “including” covers elements or items and their equivalents listed after “including” or “including”, without excluding other elements or items. Similar words such as “connect” or “connected with each other” are not limited to physical or mechanical connections, and may include electrical connections, whether direct or indirect. Terms determined by “a/an”, “the” and “said” in their singular forms in the present disclosure and the appended claims are also intended to include plural forms unless clearly indicated otherwise in the context. It should also be understood that the term “and/or” as used herein refers to and includes any or all possible combinations of one or more associated listed items.

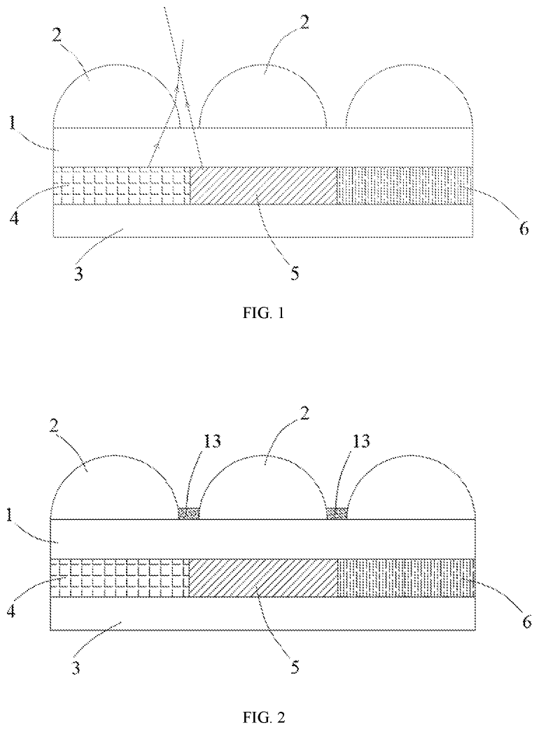

In the related art, as shown in FIG. 1, a microlens substrate includes a base 1 and a plurality of microlenses 2 disposed on the base 1. The microlens substrate is disposed on a display panel, so that a stereoscopic display device can be formed. The display panel may include a light emitting unit 3 and a color film. The color film includes a red resistance block 4, a blue resistance block 5 and a green resistance block 6. Light emitted from the light emitting unit 3 passes through the red resistance block 4, the blue resistance block 5 and the green resistance block 6 to form red light, blue light and green light respectively. Due to a gap between two adjacent microlenses 2, the light passing through the color resistance blocks will exit from the gap, which makes it easy to produce crosstalk (for example, the blue light exits from the gap and crosstalk with the red light). In order to prevent the crosstalk, as shown in FIG. 2, a black matrix 13 that can absorb light may be disposed at the gap between the adjacent microlenses 2. However, this will lead to the waste of light entering the black matrix 13 and reduce the light output efficiency. In the related art, the crosstalk can be prevented by reducing the gap between the adjacent microlenses 2 on the base 1, or it is even desired to manufacture microlenses 2 that are closely connected (that is, the gap between the microlenses 2 is zero) to greatly reduce the light emitted from the gap. During the manufacturing of the microlens substrate, a photoresist layer needs to be formed first on the base 1, then the photoresist layer is patterned to form a plurality of lens units, and next a thermal reflow process is carried out, so that the plurality of lens units are formed into a plurality of microlenses 2. Since the gap between the adjacent microlenses 2 needs to be set minimal, a gap between adjacent lens units is minimal. This easily causes the adjacent lens units to contact with each other in the thermal reflow process. The lens units that contact with each other are easy to level under the action of surface tension, and thus the plurality of microlenses 2 cannot be formed.

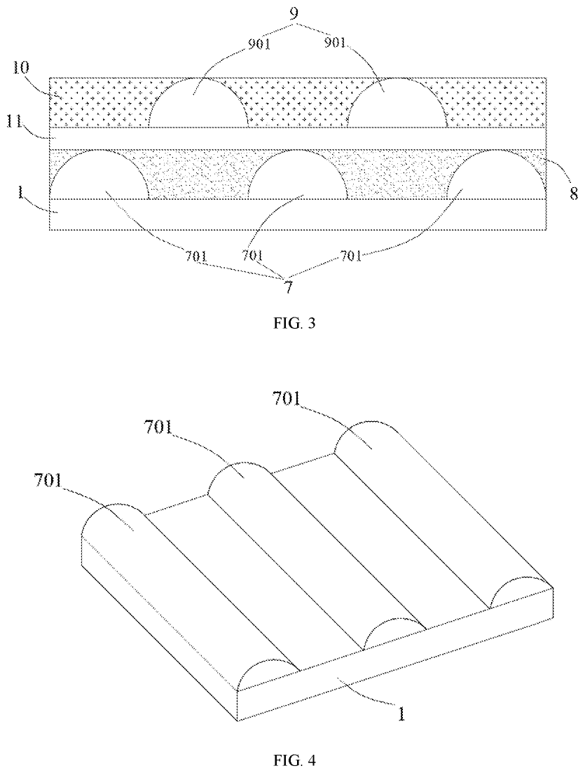

In an embodiment of the present disclosure, a microlens substrate is provided. As shown in FIG. 3, the microlens substrate may include a base 1, a first lens pattern 7 and a second lens pattern 9.

The first lens pattern 7 is disposed on a side of the base 1. The first lens pattern 7 includes a plurality of first microlenses 701 distributed at intervals. The second lens pattern 9 is disposed on a side of the first lens pattern 7. The second lens pattern 9 includes a plurality of second microlenses 901 distributed at intervals. An orthographic projection of at least one second microlens 901 on the base 1 is located between two orthographic projections of two adjacent first microlenses 701 on the base 1.

In the microlens substrate according to the embodiment of the present disclosure, the first lens pattern 7 includes a plurality of first microlenses 701 distributed at intervals, the second lens pattern 9 includes a plurality of second microlenses 901 distributed at intervals, and the orthographic projection of at least one second microlens 901 on the base 1 is located between two orthographic projections of two adjacent first microlenses 701 on the base 1. Therefore, in a direction parallel to the base 1, a gap between a first microlens 701 and a second microlens 901 adjacent to the first microlens 701 is less than that between two adjacent first microlenses 701, which is equivalent to reducing the gap between two adjacent microlenses 2 in the direction parallel to the base I so that the occurrence of light crosstalk phenomenon can be reduced. At the same time, since the gap between two adjacent first microlenses 701 is larger than that between the first microlens 701 and the second microlens 901 adjacent to the first microlens 701, that is, the gap between two adjacent first microlenses 701 is larger, on the one hand, the problem of process failure due to the contact between adjacent lens units in the thermal reflow process in the related art can be solved. On the other hand, in the present application, the black matrix 13 does not need to be disposed, so that the problem of reduction in light output efficiency due to the absorption of light by the black matrix 13 can be solved.

Each part of the microlens substrate in the embodiment of the present disclosure will be described in detail below.

The base 1 may be a rigid base. The rigid base may be a glass base, a PMMA (polymethyl methacrylate) base or the like. Alternatively, the base I may be a flexible base. The flexible base may be a polyethylene terephthalate (PET) base, a polyethylene naphtholate two formic acid glycol ester (PEN) base or a polyimide (PI) base. It is to be noted that the base 1 is a transparent base.

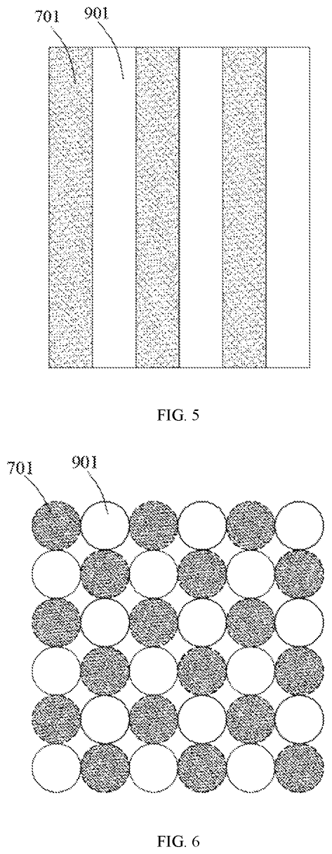

The first lens pattern 7 is disposed on a side of the base 1. Specifically, the first lens pattern 7 may be disposed on a surface of the base 1. The first lens pattern 7 includes a plurality of first microlenses 701 distributed at intervals. The plurality of first microlenses 701 are distributed at intervals in the direction parallel to the base 1. The plurality of first microlenses 701 that are distributed at intervals may be distributed in array. Each first microlens 701 may include opposite light incident surface and light outgoing surface. The light incident surface of the first microlens 701 may be attached to the base 1. The light outgoing surface of the first microlens 701 may be an outward convex surface. A refractive index of the first microlens 701 may be 1.5 to 1.8, for example, 1.5, 1.6, 1.7 or 1.8. In an embodiment of the present disclosure, as shown in FIG. 6, the orthographic projection of the first microlens 701 on the base 1 is circular or roughly circular, and a diameter of the orthographic projection of the first microlens 701 on the base 1 may be 10 μm to 300 μm, for example, 10 μm, 80 μm, 100 μm. 200 μm or 300 μm. In another embodiment of the present disclosure, as shown in FIGS. 4 and 5, the orthographic projection of the first microlens 701 on the base 1 is strip-shaped, that is, the orthographic projection is a strip-shaped orthographic projection, and a width of the strip-shaped orthographic projection may be 10 μm to 300 μm, for example, 10 μm, 60 μm, 120 μm, 230 μm or 300 μm. The width of the strip-shaped orthographic projection refers to a size of the strip-shaped orthographic projection in a first direction. The first direction is parallel to the base 1 and perpendicular to an extension direction of the strip-shaped orthographic projection. In addition, a plurality of first microlenses 701 with strip-shaped orthographic projections may be distributed at intervals in the first direction. In other embodiments of the present disclosure, the orthographic projection of the first microlens 701 on the base I may be rectangular, square or other shapes. For example, the light outgoing surface of the first microlens 701 is an outward convex surface, and a thickness of the first microlens 701 may be 5 μm to 30 μm, for example, 5 μm, 10 μm, 20 μm, 25 μm or 30 μm. The thickness of the first microlens 701 refers to a maximum size of the first microlens 701 in a thickness direction of the base 1. A material of the first microlens 701 may include photoresist. Further, the material of the first microlens 701 is photoresist.

The microlens substrate in the embodiment of the present disclosure may further include a first planarization layer 8. The first planarization layer 8 may cover light outgoing surfaces of a plurality of first microlenses 701. Further, the first planarization layer 8 may cover the first microlenses 701 and the base 1. A surface of the first planarization layer 8 facing the base 1 may be flush with light incident surfaces of the first microlenses 701. A thickness of the first planarization layer 8 may be greater than that of the first microlens 701. Alternatively, the thickness of the first planarization layer 8 may be equal to that of the first microlens 701. Specifically, the thickness of the first planarization layer 8 may be 5 μm to 30 μm, for example, 5 μm, 8 μm, 15 μm, 20 μm or 30 μm. The first planarization layer 8 may include colloidal materials, but is not limited thereto in the embodiment of the present disclosure. For example, the light outgoing surface of the first microlens 701 is an outward convex surface, and a refractive index of the first planarization layer 8 may be less than that of the first microlens 701. Specifically, the refractive index of the first planarization layer 8 may be 1.3 to 1.6. for example, 1.3. 1.4. 1.5 or 1.6. The microlens substrate in the embodiment of the present disclosure may further include a light-transmitting inorganic layer 11. The light-transmitting inorganic layer 11 may be disposed on a surface of the first planarization layer 8 away from the base 1. A material of the light-transmitting inorganic layer 11 may include silicon oxide and the like. A thickness of the light-transmitting inorganic layer 11 may be 250 nm to 350 nm, for example, 250 nm, 290 nm, 300 nm or 350 nm.

The second lens pattern 9 may be disposed on a side of the first lens pattern 7. The second lens pattern 9 may be disposed on a side of the first lens pattern 7 away from the base 1. Alternatively, the second lens pattern 9 may be disposed on a side of the first lens pattern 7 facing the base 1. For example, the second lens pattern 9 is disposed on the side of the first lens pattern 7 away from the base 1, and the second lens pattern 9 may be disposed on a surface of the light-transmitting inorganic layer 11 away from the first planarization layer 8. The second lens pattern 9 may be manufactured through a photoresist reflow process. The photoresist used in the photoresist reflow process may be evenly coated on the light-transmitting inorganic layer 11, which improves the process quality.

The second lens pattern 9 includes a plurality of second microlenses 901 distributed at intervals. The plurality of second microlenses 901 are distributed at intervals in the direction parallel to the base 1. The plurality of second microlenses 901 that are distributed at intervals may be distributed in array. Each second microlens 901 may include opposite light incident surface and light outgoing surface. The light incident surface of the second microlens 901 may be attached to the light-transmitting inorganic layer 11. The light outgoing surface of the second microlens 901 may be an outward convex surface. A refractive index of the second microlens 901 may be 1.5 to 1.8. for example. 1.5. 1.6. 1.7 or 1.8. The refractive index of the second microlens 901 may be the same as that of the first microlens 701. Further, a material of the second microlens 901 may be the same as that for the first microlens 701. A shape of an orthographic projection of the second microlens 901 on the base 1 may be the same as that of the first microlens 701 on the base 1. An area of the orthographic projection of the second microlens 901 on the base 1 may be the same as that of the first microlens 701 on the base 1. Further, a distance between two adjacent first microlenses 701 in the direction parallel to the base 1 may be the same as that between two adjacent second microlenses 901 in the direction parallel to the base 1.

In an embodiment of the present disclosure, as shown in FIG. 6, the orthographic projection of the second microlens 901 on the base 1 is circular or roughly circular, and a diameter of the orthographic projection of the second microlens 901 on the base I may be 10um to 300um. for example. 10um. 80um. 100um. 200um or 300um. In another embodiment of the present disclosure, as shown in FIG. 5. the orthographic projection of the second microlens 901 on the base I is strip-shaped. that is. the orthographic projection is a strip-shaped orthographic projection. and a width of the strip-shaped orthographic projection may be 10um to 300um. for example. 10um. 60um. 120um. 230um or 300um. The width of the strip-shaped orthographic projection refers to a size of the strip-shaped orthographic projection in the first direction. In addition. a plurality of second microlenses 901 with strip-shaped orthographic projections may be distributed at intervals in the first direction. In other embodiments of the present disclosure. the orthographic projection of the second microlens 901 on the base I may be rectangular. square or other shapes. In addition, for example. the orthographic projections of both the first microlens 701 and the second microlens 901 on the base I are strip-shaped, and the extension direction of the orthographic projection of the first microlens 701 is the same as that of the second microlens 901. For example. the light outgoing surface of the second microlens 901 is an outward convex surface. and a thickness of the second microlens 901 may be 5um to 30um. for example. 5um. 10um. 20um. 25um or 30um. The thickness of the second microlens 901 refers to a maximum size of the second microlens 901 in the thickness direction of the base 1.

As shown in FIGS. 5 and 6. an orthographic projection of at least one second microlens 901 on the base I is located between two orthographic projections of two adjacent first microlenses 701 on the base 1. Orthographic projections of a plurality of first microlenses 701 and orthographic projections of a plurality of second microlenses 901 are alternately arranged on the base 1. A distance between the orthographic projection of the second microlens 901 on the base 1 and the orthographic projection of the first microlens 701 on the base 1 is greater than or equal to zero, that is, the orthographic projection of the second microlens 901 on the base 1 does not coincide with the orthographic projection of the first microlens 701 on the base 1. Specifically, the distance between the orthographic projection of the second microlens 901 on the base 1 and the orthographic projection of the first microlens 701 on the base 1 is greater than or equal to zero and less than or equal to ¼ of a distance between two adjacent first microlenses 701. When the distance between the orthographic projection of the second microlens 901 on the base 1 and the orthographic projection of the first microlens 701 on the base 1 is equal to zero, a gap between the first microlens 701 and the second microlens 901 in the direction parallel to the base 1 is zero, which can prevent light from emitted from the gap between the first microlens 701 and the second microlens 901, and can further prevent light crosstalk. In other embodiments of the present disclosure, the orthographic projection of the second microlens 901 on the base 1 may partially coincide with the orthographic projection of the first microlens 701 on the base 1. It is to be noted that, even though the orthographic projection of the second microlens 901 on the base 1 partially coincides with the orthographic projection of the first microlens 701 on the base 1, since the first microlens 701 has a convex lens structure, which has the function of focusing light, light emitted from an edge part of the first microlens 701 (an orthographic projection of the edge part on the base 1 coincides with the orthographic projection of the second microlens 901 on the base 1) deflects toward a center of the first microlens 701 (deflects toward a direction away from the second microlens 901). In the present disclosure, only a size of a part where the orthographic projection of the second microlens 901 coincides with the orthographic projection of the first microlens 701 needs to be reasonably set, so that the second microlens 901 does not affect the light emitted from the first microlens 701.

The microlens substrate in the embodiment of the present disclosure may further include a second planarization layer 10. The second planarization layer 10 may cover light outgoing surfaces of the plurality of second microlenses 901. Further, the second planarization layer 10 may cover the second microlenses 901 and the light-transmitting inorganic layer 11. A surface of the second planarization layer 10 facing the base 1 may be flush with light incident surfaces of the second microlenses 901. A thickness of the second planarization layer 10 may be greater than that of the second microlens 901. Alternatively, the thickness of the second planarization layer 10 may be equal to that of the second microlens 901. Specifically, the thickness of the second planarization layer 10 may be 5 μm to 30 μm, for example, 5 μm, 8 μm, 15 μm, 20 μm or 30 μm. The second planarization layer 10 may include a colloidal material, but is not limited thereto in the embodiment of the present disclosure. The material of the second planarization layer 10 may be the same as that of the first planarization layer 8, or, the material of the second planarization layer 10 may be different from that of the first planarization layer 8. For example, the light outgoing surface of the second microlens 901 is an outward convex surface, and a refractive index of the second planarization layer 10 may be less than that of the second microlens 901. Specifically, the refractive index of the second planarization layer 10 may be 1.3 to 1.6, for example. 1.3, 1.4, 1.5 or 1.6.

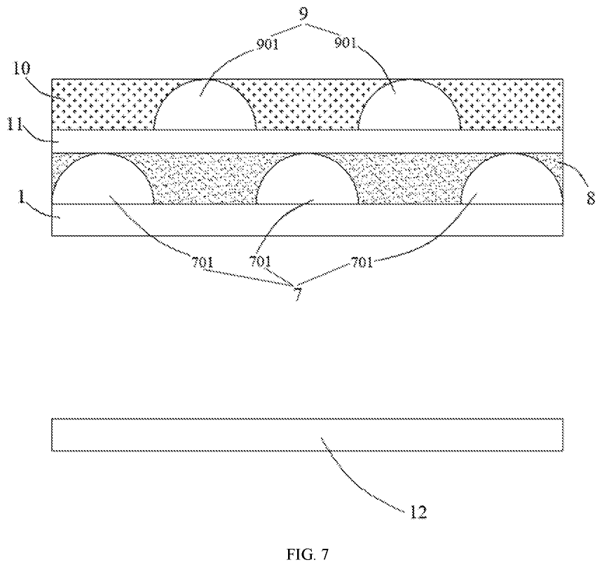

In an embodiment of the present disclosure, a display device is provided. As shown in FIG. 7, the display device may include a display module 12 and a microlens substrate according to any one of the above embodiments. The microlens substrate may be disposed on a light exiting side of the display module 12. A field of view (FOV) of the display module 12 is small, for example, ±30 20 or ±25°. in addition, a distance between a light emitting layer in the display module 12 and the microlens substrate is large, for example, 400 μm to 1000 μm. Such setting can further reduce light crosstalk. Further, the distance between the light emitting layer in the display module 12 and the microlens substrate may be 500 μm-600 μm. In an embodiment of the present disclosure, spacer glass or organic adhesive materials may be disposed between the display module 12 and the microlens substrate to increase a distance between the display module 12 and the microlens substrate and further increase the distance between the light emitting layer in the display module 12 and the microlens substrate. In other embodiments, the microlens substrate may be integrated on the display module 12. For example, the microlens substrate is formed directly on a color film substrate of the display module 12. In the present disclosure, the distance between the light emitting layer and the microlens substrate may be adjusted by changing a distance between the color film substrate and the light emitting layer in the display module 12. The display module 12 may be an OLED display module, and of course, it may be an LCD display module, etc. The display device may be a 3D display device or the like. Since the microlens substrate included in the display device in the embodiment of the present disclosure is the same as the microlens substrate in the microlens substrate embodiments as described above, they have the same beneficial effects, which will not be repeated here in the present disclosure.

In an embodiment of the present disclosure, a method for manufacturing a microlens substrate is provided. The manufacturing method is used to manufacture the microlens substrate according to any one of the above embodiments. The manufacturing method may include: providing a base 1: forming a first lens pattern 7 on a side of the base 1, where the first lens pattern 7 includes a plurality of first microlenses 701 distributed at intervals; forming a second lens pattern 9 on a side of the first lens pattern 7, where the second lens pattern 9 includes a plurality of second microlenses 901 distributed at intervals, and an orthographic projection of at least one second microlens 901 on the base 1 is located between two orthographic projections of two adjacent first microlenses 701 on the base 1.

The first lens pattern 7 may be formed through a first photoetching process, specifically including: forming a first photoresist layer on the base 1: patterning the first photoresist layer through a mask plate, and forming the plurality of first microlenses 701 through a thermal reflow process. The second lens pattern 9 may be formed through a second photoetching process, specifically including: forming a second photoresist layer on a light-transmitting inorganic layer 11: patterning the second photoresist layer through a mask plate, and forming the plurality of second microlenses 901 through the thermal reflow process. The mask plate used in the first photoetching process and the mask plate used in the second photoetching process are the same mask plate, which can reduce the number of mask plates and reduce the cost.

The above are only preferred embodiments of the present disclosure, which are not intended to make any formal limitation on the disclosure. Although the present disclosure has been disclosed as above in the preferred embodiments, these preferred embodiments are not intended to limit the present disclosure, and any person skilled in the art, without departing from the scope of the technical solutions of the present disclosure, can make some changes or modifications to the technical contents disclosed above as equivalent embodiments with equivalent changes. However, without departing from the contents of the technical solutions of the present disclosure, any simple revisions, equivalent changes and modifications made to the above embodiments based on the technical essence of the present disclosure still fall within the scope of the technical solutions of the present disclosure.

1. A microlens substrate, comprising:
a base;
a first lens pattern disposed on a side of the base and comprising a plurality of first microlenses distributed at intervals;
a second lens pattern disposed on a side of the first lens pattern and comprising a plurality of second microlenses distributed at intervals, wherein an orthographic projection of at least one of the plurality of second microlenses on the base is located between two orthographic projections of two adjacent first microlenses on the base.

2. The microlens substrate according to claim 1, wherein a distance between an orthographic projection of a second microlens on the base and an orthographic projection of a first microlens on the base is greater than or equal to zero and less than or equal to ¼ of a distance between two adjacent first microlenses.

3. The microlens substrate according to claim 1, further comprising:
a first planarization layer covering light exiting surfaces of the plurality of first microlenses, wherein the light exiting surfaces of the plurality of first microlenses are respectively outward convex surfaces, and a refractive index of the first planarization layer is less than that of each of the plurality of first microlenses.

4. The microlens substrate according to claim 3, wherein the second lens pattern is disposed on a side of the first planarization layer away from the plurality of first microlenses, and light exiting surfaces of the plurality of second microlenses face away from the plurality of first microlenses.

5. The microlens substrate according to claim 4, further comprising:
a second planarization layer covering the light exiting surfaces of the plurality of second microlenses, wherein the light exiting surfaces of the plurality of second microlenses are respectively outward convex surfaces, and a refractive index of the second planarization layer is less than that of each of the plurality of second microlenses.

6. The microlens substrate according to claim 5, wherein
the refractive index of each of the plurality of first microlenses is 1.5 to 1.8; and/or
the refractive index of each of the plurality of second microlenses is 1.5 to 1.8; and/or
the refractive index of the first planarization layer is 1.3 to 1.6; and/or
the refractive index of the second planarization layer is 1.3 to 1.6.

7. The microlens substrate according to claim 5, further comprising:
a light-transmitting inorganic layer disposed on the side of the first planarization layer away from the plurality of first microlenses, wherein the plurality of second microlenses are disposed on a surface of the light-transmitting inorganic layer away from the first planarization layer.

8. The microlens substrate according to claim 7, wherein
a thickness of the first planarization layer is 5 μm to 30 μm; and/or
a thickness of each of the plurality of first microlenses is 5 μm to 30 μm; and/or
a thickness of the second planarization layer is 5 μm to 30 μm; and/or
a thickness of each of the plurality of second microlenses is 5 μm to 30 μm; and/or
a thickness of the light-transmitting inorganic layer is 250 nm to 350 nm.

9. The microlens substrate according to claim 1, wherein for each of the plurality of first microlenses and each of the plurality of second microlenses,
at least one of an orthographic projection of the first microlens on the base or an orthographic projection of the second microlens on the base are circular or strip-shaped.

10. The microlens substrate according to claim 9, wherein,
when the orthographic projection of the first microlens on the base and the orthographic projection of the second microlens on the base are circular, a diameter of the orthographic projection of the first microlens on the base and a diameter of the orthographic projection of the second microlens on the base are 10 μm to 300 μm;
when the orthographic projection of the first microlenses on the base and the orthographic projection of the second microlens on the base are strip-shaped, a width of the orthographic projection of the first microlens on the base and a width of the orthographic projection of the second microlens on the base are 10 μm to 300 μm.

11. The microlens substrate according to claim 1, wherein materials for the plurality of first microlenses and/or the plurality of second microlenses comprise photoresist.

12. The microlens substrate according to claim 1, wherein for each of the plurality of first microlenses and each of the plurality of second microlenses,
a shape of an orthographic projection of the first microlens on the base is the same as that of the second microlens on the base, an area of the orthographic projection of the first microlens on the base is the same as that of the second microlens on the base, and a distance between two adjacent first microlenses in a direction parallel to the base is the same as that between two adjacent second microlenses in the direction parallel to the base.

13. A display device, comprising:
a display module;
a microlens substrate according to claim 1 disposed on a light exiting side of the display module.

14. A method of manufacturing a microlens substrate, comprising:
providing a base;
forming a first lens pattern on a side of the base, wherein the first lens pattern comprises a plurality of first microlenses distributed at intervals;
forming a second lens pattern on a side of the first lens pattern, wherein the second lens pattern comprises a plurality of second microlenses distributed at intervals, and an orthographic projection of at least one of the plurality of second microlenses on the base is located between two orthographic projections of two adjacent first microlenses on the base.

15. The method of manufacturing a microlens substrate according to claim 14, wherein
forming the first lens pattern comprises: forming the first lens pattern through a first photoetching process;
forming the second lens pattern comprises: forming the second lens pattern through a second photoetching process;
wherein a mask plate used in the first photoetching process and a mask plate used in the second photoetching process are the same mask plate.

16. The method of manufacturing a microlens substrate according to claim 14, wherein a distance between an orthographic projection of a second microlens on the base and an orthographic projection of a first microlens on the base is greater than or equal to zero and less than or equal to ¼ of a distance between two adjacent first microlenses.

17. The method of manufacturing a microlens substrate according to claim 14, further comprising:
forming a first planarization layer covering light exiting surfaces of the plurality of first microlenses, wherein the light exiting surfaces of the plurality of first microlenses are respectively outward convex surfaces, and a refractive index of the first planarization layer is less than that of each of the plurality of first microlenses.

18. The method of manufacturing a microlens substrate according to claim 17, wherein the second lens pattern is disposed on a side of the first planarization layer away from the plurality of first microlenses, and light exiting surfaces of the plurality of second microlenses face away from the plurality of first microlenses.

19. The method of manufacturing a microlens substrate according to claim 18, further comprising:
forming a second planarization layer covering the light exiting surfaces of the plurality of second microlenses, wherein the light exiting surfaces of the plurality of second microlenses are respectively outward convex surfaces, and a refractive index of the second planarization layer is less than that of each of the plurality of second microlenses.

20. The method of manufacturing a microlens substrate according to claim 19, further comprising:
forming a light-transmitting inorganic layer disposed on the side of the first planarization layer away from the plurality of first microlenses, wherein the plurality of second microlenses are disposed on a surface of the light-transmitting inorganic layer away from the first planarization layer.
